(19) United States
(12) Patent Application Publication
(10) Pub. No.: US 2021/0257213 A1
(43) Pub. Date: Aug. 19, 2021

(54) METHOD OF FORMING DIELECTRIC MATERIAL LAYERS USING PULSED PLASMA POWER, STRUCTURES AND DEVICES INCLUDING THE LAYERS, AND SYSTEMS FOR FORMING THE LAYERS

(71) Applicant: ASM IP Holding B.V., Almere (NL)

(72) Inventors: Yoshiyuki Kikuchi, Tokyo (JP); Norihiko Ishinohachi, Tama, Tokyo (JP)

(21) Appl. No.: 17/172,738

(22) Filed: Feb. 10, 2021

Related U.S. Application Data
(60) Provisional application No. 62/976,796, filed on Feb. 14, 2020.

(51) Int. Cl. H01L 21/02; B05D 1/00

(52) U.S. Cl. CPC H01L 21/02274; H01L 21/02118; H01L 21/02216; H01L 23/5329; H01L 21/0234; H01L 21/02348; H01L 21/02345; B05D 1/62

(57) ABSTRACT

Methods and systems for forming a structure including a dielectric material layer on a surface of a substrate and structures and devices formed using the method or system are disclosed. Exemplary methods include providing a substrate within a reaction chamber of a reactor system, providing one or more precursors to the reaction chamber, and providing pulsed plasma power to polymerize the one or more precursors within the reaction chamber.

### CROSS-REFERENCE TO RELATED APPLICATIONS

This application claims the benefit of and priority to U.S. Provisional Application No. 62/976,796, filed on Feb. 14, 2020 in the United States Patent and Trademark Office, the disclosure of which is incorporated herein in its entirety by reference.

### FIELD OF INVENTION

The present disclosure generally relates to methods of forming layers and structures suitable for use in the manufacture of electronic devices. More particularly, examples of the disclosure relate to methods of forming structures that include dielectric layers, to structures and devices including such layers, and to systems for performing the methods and/or forming the structures and/or devices.

### BACKGROUND OF THE DISCLOSURE

During the manufacture of devices, such as semiconductor devices, it is often desirable to fill features (e.g., trenches or gaps) on the surface of a substrate with dielectric material. In some cases, it may be desirable to fill the features with a low dielectric constant (low-k) material, such as carbon material (e.g., silicon oxygen carbide material) or other dielectric material, such as silicon oxide (SiOₓ), silicon nitride (SiNₓ), or the like. By way of examples, dielectric material can be used as an intermetal dielectric layer on patterned metal features, a gap fill for fully aligned vias in back-end-of-line processes, an inner isolation layer for gate all around devices, insulating layers in resistive random-access memory (ReRAM) devices, and the like.

Some dielectric material deposition processes can use organic silanes or oxysilanes and an oxidant to form an initially flowable material. The material can be deposited using thermal energy or a remote plasma to activate the oxidant. Such techniques often include relatively long curing or annealing steps to increase a density of the deposited material and to reduce a dielectric constant of the material.

Although these techniques can work well for some applications, filling features using traditional deposition techniques has several shortcomings, particularly as the size of the features to be filled decreases. For example, a dielectric constant of the cured or annealed material can vary significantly using conventional techniques, leading to undesired variation in device performance. In addition, dielectric material formed using these techniques can be prone to cracking. Additionally, the deposition steps and/or post deposition steps (e.g., annealing or curing) can be relatively long.

Accordingly, improved methods for forming dielectric material layer on a surface of a substrate, particularly for methods of filling gaps on a substrate surface with such material, that mitigate variation of the dielectric constant of the material and/or that provide desired material properties (e.g., less or no cracking and/or less or few voids or seams) and/or that can be performed relatively quickly, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures suitable for use in the formation of electronic devices. While the ways in which various embodiments of the present disclosure address drawbacks of prior methods and structures are discussed in more detail below, in general, exemplary embodiments of the disclosure provide improved methods for forming structures that include dielectric material, structures including the dielectric material, and systems for performing the methods and/or forming the structures. The methods described herein can be used to fill features on a surface of a substrate.

In accordance with various embodiments of the disclosure, methods of forming a dielectric layer on a surface of a substrate are provided. Exemplary methods include providing a substrate within a reaction chamber of a reactor system, providing one or more precursors to the reaction chamber, and providing pulsed plasma power to polymerize the precursor within the reaction chamber. A dielectric material layer forms as the one or more precursors are polymerized. As the one or more precursors are polymerized, the material that forms can initially be flowable and flow into features on a surface of a substrate to fill the features or gaps between features. In accordance with exemplary aspects of these embodiments, methods can additionally include a step of providing a reactant to the reaction chamber. The reactant can include, for example, nitrogen and/or hydrogen. In accordance with further examples of the disclosure, the reactant can include an oxidant. In accordance with further examples of the disclosure, the methods are performed using a plasma-enhanced chemical vapor deposition (PECVD) process. The methods can include use of a direct and/or a remote plasma. In accordance with additional examples of the disclosure, the one or more precursors comprise a compound comprising silicon and/or carbon. Methods can include a thermal curing step. The thermal curing can be performed in the presence of, for example, an oxidant. A temperature of the substrate during the step of thermal curing can be less than 500° C. Exemplary methods can additionally include a step of performing a post-deposition treatment using one or more of capacitively coupled plasma (CCP), microwave excitation, very high frequency (VHF) excitation, and ultraviolet (UV) excitation of/with an inert gas.

In accordance with yet further exemplary embodiments of the disclosure, a structure is formed, at least in part, according to a method described herein. The structure can include a dielectric material layer. The dielectric material layer can be deposited over features having an aspect ratio 1:1 or more.

In accordance with further examples of the disclosure, a device can be formed using a method and/or include a structure as described herein. The device can be or include, for example, a FinFET, a gate all around nanowire FET, an cross-point cell, a memory device, or a logic device.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a portion of a method in accordance with examples of the disclosure.

FIG. 3 illustrates a structure in accordance with exemplary embodiments of the disclosure.

FIG. 4 illustrates carbon bonding status of material deposited in accordance with exemplary embodiments of the disclosure.

FIG. 5 illustrates a system in accordance with exemplary embodiments of the disclosure.

FIG. 6 illustrates a FinFET structure including a dielectric material layer in accordance with exemplary embodiments of the disclosure.

FIG. 7 illustrates a gate all around device structure including a dielectric material layer in accordance with further exemplary embodiments of the disclosure.

FIG. 8 illustrates a cross-point device structure including a dielectric material layer in accordance with exemplary embodiments of the disclosure.

FIG. 9 illustrates a device structure including a back end of line intermetal dielectric gapfill layer in accordance with exemplary embodiments of the disclosure.

FIG. 10 illustrates a device structure including a back end of line fully aligned via structure and a gapfill layer in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing dielectric material layers, to methods of forming structures and devices, to structures and devices formed using the methods, and to systems for performing the methods and/or forming the structures and devices. By way of examples, the methods described herein can be used to fill features, such as gaps (e.g., trenches or vias) on a surface of a substrate with the dielectric material. The terms gap and recess can be used interchangeably.

To mitigate void and/or seam formation during a gap-filling process, deposited material can be initially flowable and flow within the gap to fill the gap. Exemplary structures described herein can be used in a variety of applications and devices, including, but not limited to, cell isolation in 3D cross-point memory devices, self-aligned vias, dummy gates, reverse tone patterns, PC RAM isolation, cut hard masks, DRAM storage node contact (SNC) isolation, as an intermetallic gap-fill layer on or between patterned metal features (which can include, for example, one or more of Ru, Co, Cu, Ta, TaN, Ti, TiN, W), a gap fill for fully aligned vias in back-end-of-line (BEOL) processes, a dielectric on dielectric in BEOL processes—e.g., for memory or logic devices, inner isolation for gate all around devices, insulating layers in resistive random-access memory (ReRAM) devices, a shallow trench isolation layer of a FinFET device, and the like.

In this disclosure, “gas” can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than a precursor, that activates a precursor, modifies a precursor, or catalyzes a reaction of a precursor; a reactant may provide an element (such as O, H, N, C) to a film matrix and become a part of the film matrix when, for example, power (e.g., radio frequency (RF) power) is applied. In some cases, the terms precursor and reactant can be used interchangeably. In some cases, a reactant can include a plurality of compounds. The term “inert gas” refers to a gas that does not take part in a chemical reaction to an appreciable extent and/or a gas that excites a precursor (e.g., to facilitate polymerization of the precursor) when, for example, power (e.g., RF power) is applied, but unlike a reactant, it may not become a part of a film matrix to an appreciable extent. Exemplary inert gases include argon, helium, nitrogen, and any mixture thereof.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate. By way of examples, one or more features can have a width of about 10 nm to about 100 nm, a depth or height of about 30 nm to about 1,000 nm, and/or an aspect ratio of about 1:1, 1:3, 1:10, 1:100, or more.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “low-k material layer” or “low-k material” can refer to material whose dielectric constant is less than the dielectric constant of silicon dioxide or less than 3.8 or between about 2.5 and about 3. Dielectric materials include low-k materials and other materials, such as oxides (e.g., silicon oxides) and nitride (e.g., silicon nitrides). In accordance with examples of the disclosure, a dielectric constant of the dielectric materials is between about 2.2 and about 4.2 or less than 10.

As used herein, the term “structure” can refer to a partially or completely fabricated device structure. By way of examples, a structure can be a substrate or include a substrate with one or more layers and/or features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic chemical vapor deposition (CVD) and atomic layer deposition (ALD) processes. A cyclic deposition process can include one or more cycles that include plasma activation of a precursor, a reactant, and/or an inert gas.

In this disclosure, “continuously” can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top | |
|---|---|
| ratio (B/T) | Flowability |
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited at a top surface where the recess is formed, before the recess is filled. Typically, the flowability is evaluated using a wide recess having an aspect ratio of about 1:1 or less, since generally, the higher the aspect ratio of the recess, the higher the B/T ratio becomes. The B/T ratio generally becomes higher when the aspect ratio of the recess is higher. As used herein, a “flowable” film or material exhibits good or better flowability.

As set forth in more detail below, flowability of material can be temporarily obtained when one or more precursors are polymerized by, for example, excited species formed using a plasma. The resultant polymer material can exhibit temporarily flowable behavior. When a deposition step is complete and/or after a short period of time (e.g., about 3.0 seconds), the film may no longer be flowable, but rather becomes solidified, and thus, a separate solidification process may not be employed. In some cases, a curing step can be used.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

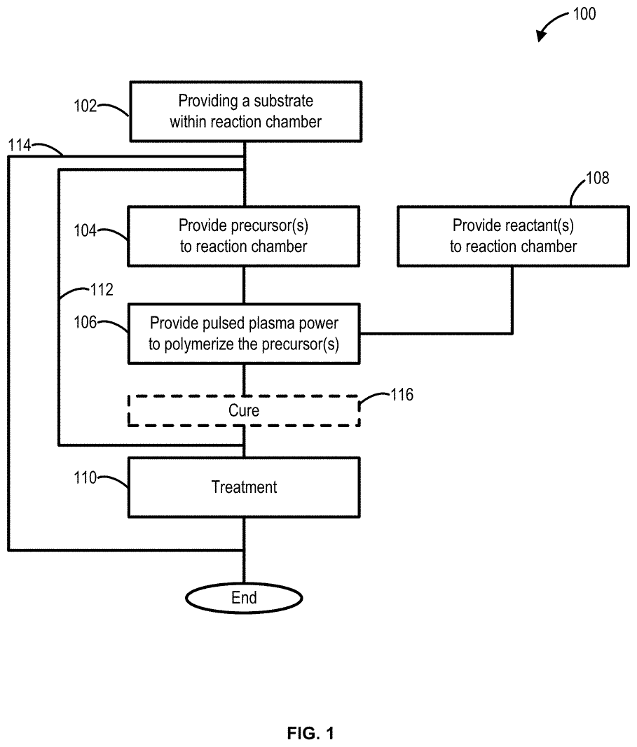

FIG. 1 illustrates a method 100 of forming a dielectric material layer on a surface of a substrate in accordance with exemplary embodiments of the disclosure. Method 100 includes the step of providing a substrate within a reaction chamber (step 102), providing one or more precursors to the reaction chamber (step 104), and providing pulsed plasma power to polymerize the one or more precursors within the reaction chamber (step 106). Method 100 can also include a step of providing one or more reactants to the reaction chamber (step 108) and/or a treatment step (step 110) and/or a curing step (step 116). As illustrated, method 100 can include repeating steps 104-108 and 116 a number of times prior to step 110 (loop 112) and/or repeating steps 104-110 and 116 a number of times, where steps 108 and/or 116 may be optional in at least some cases.

During step 102, a substrate is provided into a reaction chamber of a gas-phase reactor. In accordance with examples of the disclosure, the reaction chamber can form part of a chemical vapor deposition reactor, such as a plasma-enhanced chemical vapor deposition (PECVD) reactor or plasma-enhanced atomic layer deposition (PEALD) reactor. Various steps of methods described herein can be performed within a single reaction chamber or can be performed in multiple reaction chambers, such as reaction chambers of a cluster tool.

During step 102, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than or equal to 450° C. or less than or equal to 300° C. or less than or equal to 200° C. In accordance with particular examples of the disclosure, the substrate includes one or more features, such as recesses.

During providing one or more precursors to the reaction chamber step 104, one or more precursors for forming the dielectric material layer are introduced into the reaction chamber. Exemplary precursors can include a compound comprising carbon and/or silicon. In accordance with examples of the disclosure, the one or more precursors comprise a compound comprising a cyclic structure. The cyclic structure can include silicon—e.g., silicon and oxygen. The one or more precursors can include a compound that includes Si—O bonds. The one or more precursors can include a compound that includes an organosilicon compound, such as a cyclic organosilicon compound. The one or more precursors can include a compound that includes a siloxane. Particular exemplary siloxanes include one or more of octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethlsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), and dicyclopentyldimethoxysilane (DcPDMS). In accordance with further examples of the disclosure, the one or more precursors comprise an amino-alkyl siloxane precursor, such as 1,3-bis(3aminopropyl)tetramethyldisiloxane. In accordance with additional examples of the disclosure, the at least one of the one or more precursors comprises a ring structure comprising a chemical formula represented by —(Si(R₁,R₂)—O)ₙ—, where n ranges from about 30 to about 10 or about 3 to about 6. By way of particular examples, wherein n can be 4 and R₁═R₂═CH₃; or n can be 4, R₁═H, and R₂═CH₃. In accordance with further examples, at least one of the one or more precursors comprises a linear structure comprising a chemical formula represented by R₃—(Si(R₁,R₂)ₘ—O₍ₘ₋₁₎)—R₄, where m can range from about 1 to about 7 to about 1 to about 4. By way of particular examples, m can be 1, R₁═R₂═CH₃, and R₃═R₄═OCH₃; m can be 2, R₁═R₂═CH₃, and R₃═R₄═OCH₃; or m can be 2, R₁═C₃H₆—NH₂, R₂═CH₃, and R₃═R₄═CH₃.

A flowrate of the one or more precursors to the reaction chamber can vary according to other process conditions. By way of examples, the flowrate can be from about 100 sccm to about 3,000 sccm. Similarly, a duration of each step of providing a carbon precursor to the reaction chamber can vary, depending on various considerations. During step 108, one or more reactants can be provided to the reaction chamber. The one or more reactants can be flowed to the reaction chamber at the same time or overlapping in time with the step of providing one or more precursors to the reaction chamber. In this case, a CVD reaction can occur. In some cases, the reactant and or the one or more precursors can be pulsed to the reaction chamber for a cyclical process, such as a cyclical CVD or ALD process.

Exemplary reactants provided during step 108 include compounds including one or more of nitrogen and hydrogen. For example, a reactant including one or more of nitrogen and hydrogen can include one or more of NH₃, nitrogen, hydrogen, and amino family reactants, such as hydrazine, monomethylamine, dimethylamine, trimethylamine, monoethylamine, and diethylamine, in any combination.

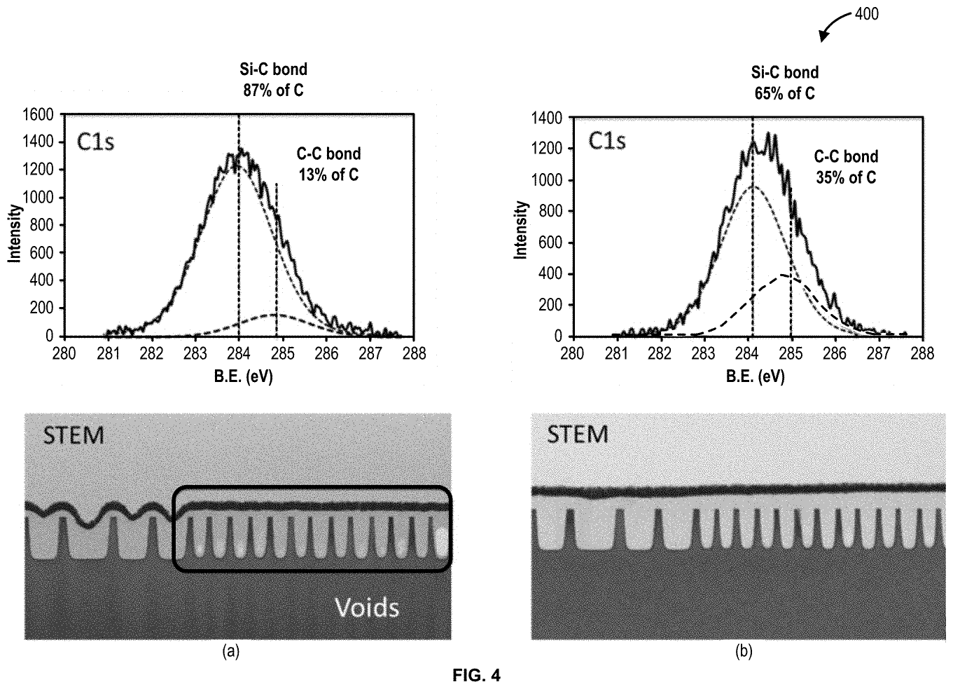

The reactant including one or more of nitrogen and hydrogen can be used to control a flowability of polymerized material as it forms. With reference to FIG. 4, addition of a reactant including one or more of nitrogen and hydrogen (e.g., NH₃) into a precursor plasma improved deposition properties of the dielectric material layer by mitigating void formation between narrow features and decreasing the deposition rate of the dielectric material layer. FIG. 4(a) illustrates C1 data and scanning transmission electron microscopy (STEM) images of a dielectric material layer deposited without a reactant including one or more of nitrogen and hydrogen; FIG. 4(b) illustrates C1 data and STEM images of a dielectric material layer deposited with a reactant including one or more of nitrogen and hydrogen. As illustrated, use of a reactant including one or more of nitrogen and hydrogen facilitates control of void formation and causes an increase in C—C bonding. This is thought to be due to the reactant (e.g., excited NH₃) preferentially attacking groups (e.g., methyl groups) of one or more precursors, while maintaining a skeletal (e.g., ring or linear backbone) structure of the one or more precursors. This mechanism is thought to allow better control of polymerization of the one or more precursors.

A reactant can additionally or alternatively include an oxidant. The oxidant can include one or more of O₂, O₃, N₂O, N₂O₄, NₓO_{y}, CO, CO₂, H₂O, and H₂O₂, and oxygen-containing (e.g., liquid) compounds represented by the chemical formula: CₓH_{y}O_{z}, where x is between 1 and 5, y is between 4 and 16, and Z is between 1 and 4, such as methanol, ethanol, and isopropyl alcohol, in any combination. The oxidant is thought to reduce excess carbon in film and increase connectivity of film structure, which in turn, is thought to reduce layer shrinkage during subsequent processing, such as annealing (e.g., at a temperature of 400° C.).

In accordance with further examples of the disclosure, a volumetric ratio (e.g., within or flowing to the reaction chamber) of the reactant compounds including one or more of nitrogen and hydrogen to the one or more precursors can be less than 10 or about 3 to about 5. In accordance with further examples, a volumetric ratio (e.g., within or flowing to the reaction chamber) of the oxidant to the one or more precursors can be less than 10 or about 7 to about 10.

During the step of providing pulsed plasma power to polymerize the one or more precursors within the reaction chamber step 106, the one or more precursors provided to the reaction chamber are polymerized into the initially viscous material using excited species. The initially viscous carbon material can become solid material—e.g., through further reaction with excited species and/or during curing step 116. Step 106 can include, for example, PECVD, PEALD, or PE cyclical CVD.

The plasma can be generated using a direct plasma system, described in more detail below, and/or using a remote plasma system. A power used to generate the plasma during step 106 can be less than 2000 W or be between about 300 W and about 500 W. A frequency of the power can range from 1000 kHz to 200 MHz with single or dual (e.g., RF) power sources. In some cases, a frequency of power for the step of providing pulsed plasma power comprises a high RF frequency (e.g., over 1 MHz or about 13.56 MHz) and a low RF frequency (e.g., less than 500 kHz or about 430 kHz). The lower frequency power can be applied to either an anode or a cathode of a plasma generation system. A pulse on time of the low RF frequency power can be about 1 kHz to about 100 kHz and duty cycle can be about 10% to about 100% or less than 50%.

During step 106, the plasma power is pulsed. Pulsing the plasma power is thought to facilitate control of a sticking coefficient of excited precursors on a substrate surface. Generally, a small sticking coefficient is thought to help surface migration and diffusion of polymers as they form.

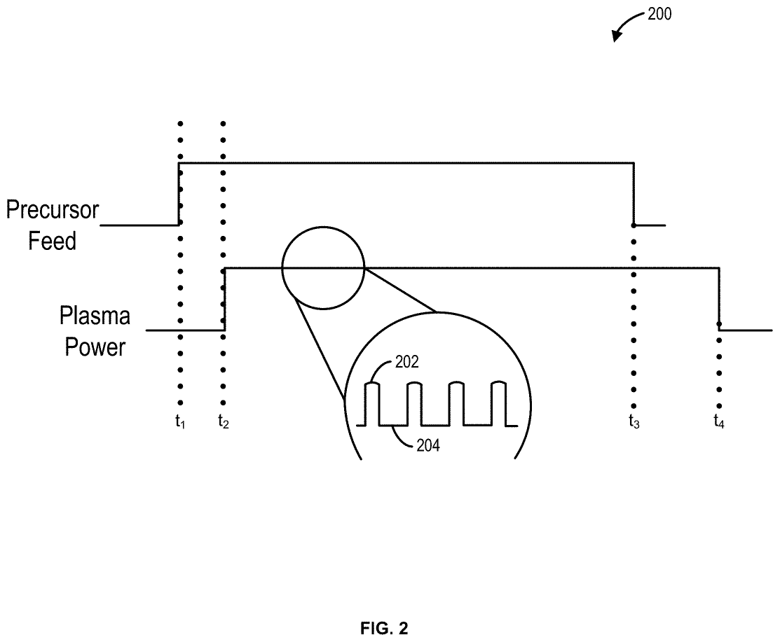

FIG. 2 illustrates a pulse plasma step in accordance with examples of the disclosure. As illustrated in FIG. 1 and FIG. 2, step 104 of providing one or more precursors can begin at a time t1. Optionally, one or more reactants can be provided to the reaction chamber at t1 or prior to t2. Thereafter, at t2, plasma power is provided to polymerize the one or more precursors. At t3, a flow of the one or more precursors and/or reactant(s) is ceased, and at t4, the power to form the plasma is reduced to extinguish the plasma.

During the period between t2 and t4, the plasma power can be pulsed, as illustrated in the enlarged portion of FIG. 2. A pulse can include a pulse on time 202 and a pulse off time 204, which can be repeated during t2-t4. Pulse on time 202 for the pulsed plasma power can be less than 50 μseconds, or about 10 μseconds to about 20 μseconds. Pulse off time 204 can be longer than pulse on time 202—e.g., greater than 2 or 5 times the pulse on time, or about 7 to about 10 times the pulse on time. Or, the RF on duty cycle can be less than 50%. The relatively short RF on time and relatively long RF off time is thought to enable control of the flowable deposition process by affecting the sticking coefficient of the polymerized precursor(s). If a long RF on time is applied, an amount of precursor(s) excitation may be too much in gas phase, resulting in large particles, such as flakes forming in the gas phase. Also, shorter RF off times can result in particle and void formation due to lack of enough surface migration. By controlling chemical reactions and sticking coefficiency of precursors at the substrate surface using a pulsed plasma, both of good gap-filling capability and high film qualities of deposited dielectric material layer are achieved.

Optional curing step 116 can include thermal curing—i.e., the substrate and reactants may not be exposed to a plasma during the thermal curing. During step 116, an oxidant and an inert gas can be provided. The oxidant can be selected from, for example, one or more of COₓ, O₂, O₃, isopropyl alcohol, H₂O, or other oxidant noted herein, in any combination. A temperature of the substrate during the step of the thermal curing can be less than 500° C. Treatment step 110 can include treating polymerized material on a surface of a substrate. During step 110, one or more of capacitively coupled plasma (CCP), microwave excitation, very high frequency (VHF) excitation, and ultraviolet (UV) excitation of/with an inert gas can be used to, for example, densify the deposited material, lower the dielectric constant of the deposited material, or the like. A temperature of the substrate during the step of performing the post-deposition treatment is less than 500° C.

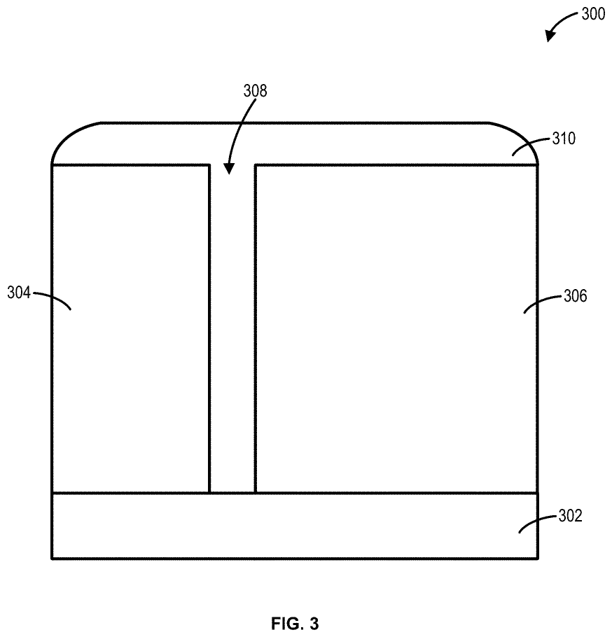

FIG. 3 illustrates a structure 300 in accordance with further examples of the disclosure. Structure 300 includes a substrate 302, one or more features 304, 306, a gap 308 between features 304, 306, and a dielectric material layer 310. Structure 300 can be used to manufacture a variety of devices and/or for a variety of applications, including a shallow trench isolation layer for FET devices, including FinFET shallow trench isolation gap fill applications, gate all around nanowire device isolation gap fill applications, cross-point devices, memory or logic devices, and the like.

Substrate 302 can be or include any suitable substrate material, such as the substrate (bulk and/or layer) materials noted herein. In some cases, substrate 302 can include insulating or dielectric material. In these cases, the structure can include a dielectric layer on dielectric (DOD) gap fill structure comprising dielectric material layer 310. DOD gap fill structure can be useful in BEOL processes, particularly in logic and memory device manufacturing.

Features 304, 306 can be formed of a variety of materials, such as insulating, semiconducting, or conducting materials. By way of examples, features 304, 306 can be intermetallic features comprising one or more of Ru, Co, Cu, Ta, TaN, Ti, TiN, W, wherein dielectric material layer 310 forms an intermetallic gap-fill layer between two or more of the features 304, 306.

Dielectric material layer 310 can be formed according to a method described herein. In accordance with examples of the disclosure, dielectric material layer 310 comprises silicon, oxygen, and carbon. Dielectric material layer 310 can include various properties of dielectric material layers noted herein.

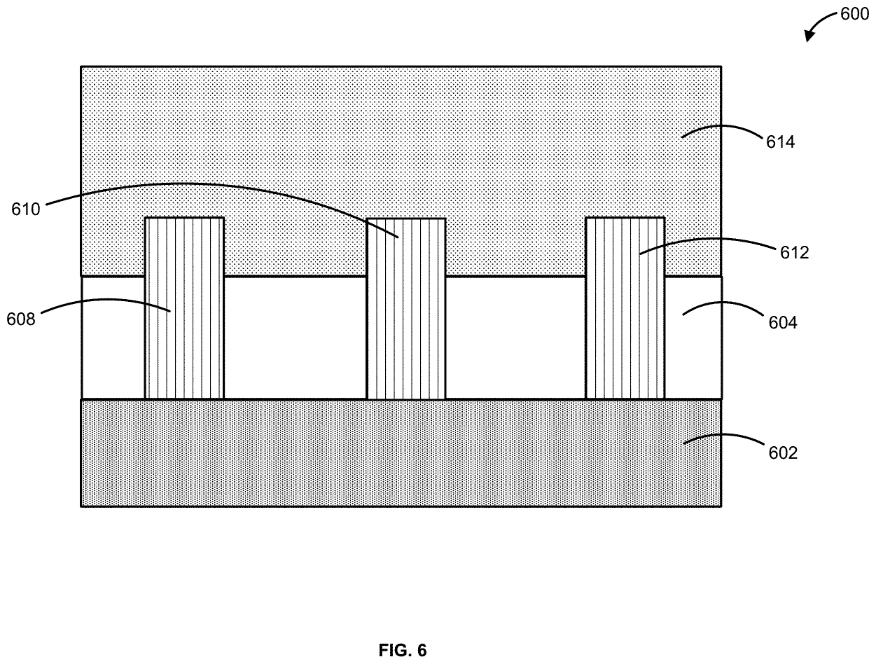

FIG. 6 illustrates a FinFET structure 600 in accordance with additional examples of the disclosure. FinFET structure 600 includes a substrate 602, a fin 604, gate features 608-612, and a dielectric material layer 614.

Substrate 602 can include any suitable substrate materials, such as the substrate materials described herein. Fin 604 can include one or more lateral nanowires including, for example, at least one of: silicon, germanium, silicon germanium, combinations thereof, or other semiconductor material. Gate structures 608-612 can include, for example, a dielectric layer and a conductive layer. Dielectric material layer 614 can include a dielectric material layer formed using a method described herein.

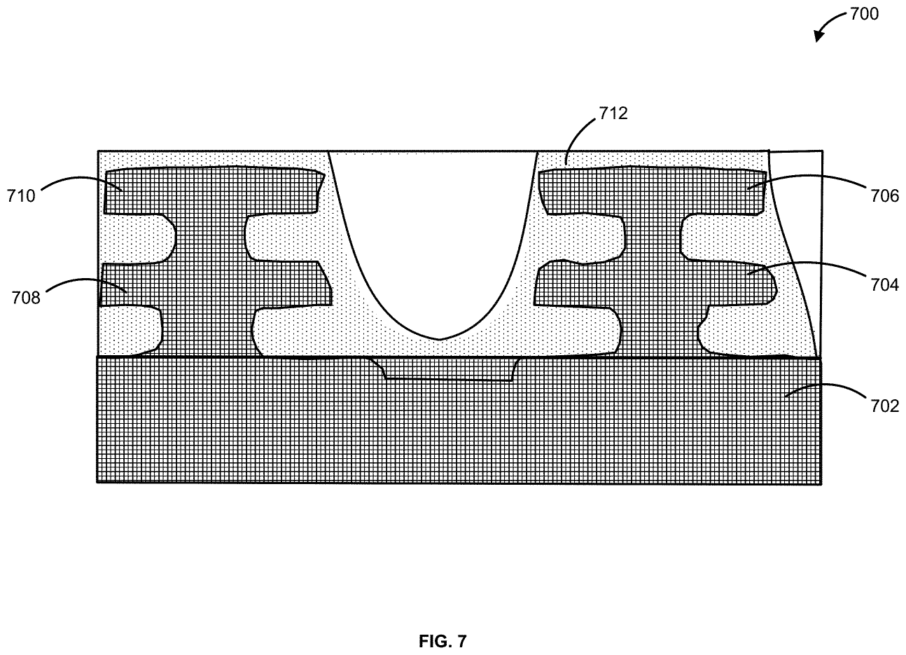

FIG. 7 illustrates a gate all around device structure 700 in accordance with further exemplary embodiments of the disclosure. Gate all around device structure 700 includes a substrate 702, fins 704-710, and a dielectric material layer 712. Substrate 702 can include any suitable substrate materials, such as the substrate materials described herein. Fins 704-710 can include semiconductive material, such as, for example, at least one of: silicon, germanium, silicon germanium, combinations thereof. Gate structures can include, for example, a dielectric layer and metal layer. Dielectric material layer 712 can be or include a dielectric material layer formed using a method described herein.

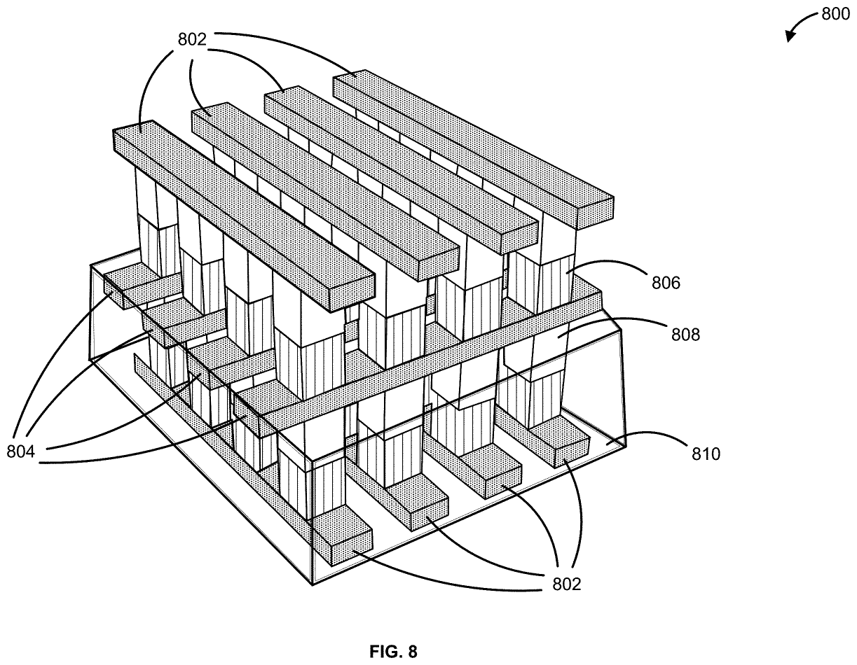

FIG. 8 illustrates a cross-point (e.g., memory) device structure 800 in accordance with further exemplary embodiments of the disclosure. Cross-point device structure 800 includes a plurality of bit lines 802, a plurality of word lines 804, a plurality of memory elements 806, a plurality of selector devices 808, and a dielectric material layer 810 surrounding at least a portion of the memory elements 806 and/or selector devices 808. Dielectric material layer 810 can include a dielectric material layer formed using a method described herein.

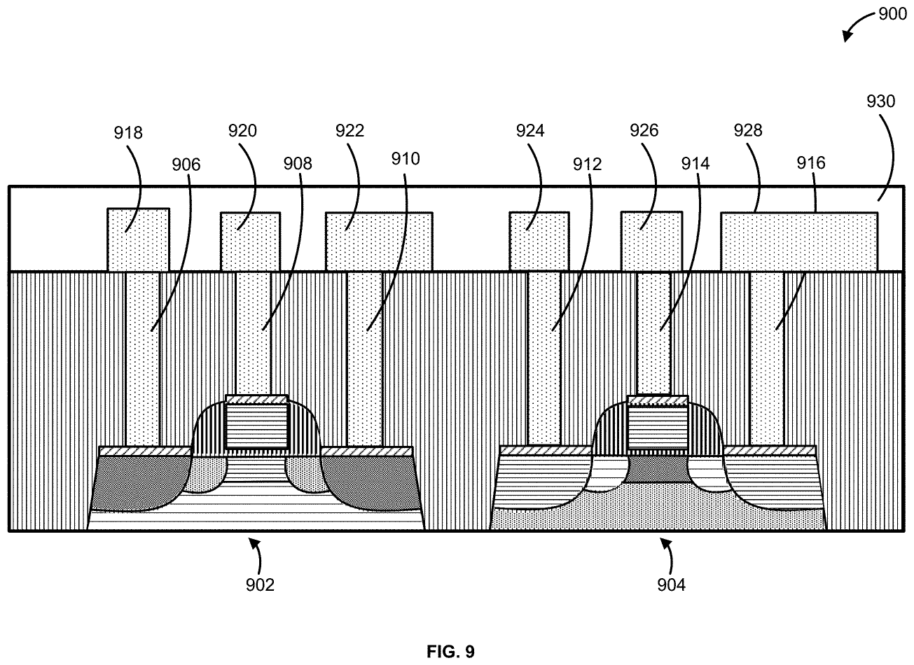

FIG. 9 illustrates a device structure 900 in accordance with additional exemplary embodiments of the disclosure. Structure 900 includes a first device 902, a second device 904, conductive plugs 906-916, interconnect structures 918-928, and a dielectric material layer 930 surrounding at least a portion of interconnect structures 918-928. Dielectric material layer 930 can include a dielectric material layer formed using a method described herein. FIG. 9 illustrates use of a method described herein for back end of line (BEOL) intermetal dielectric (IMD) gap fill applications.

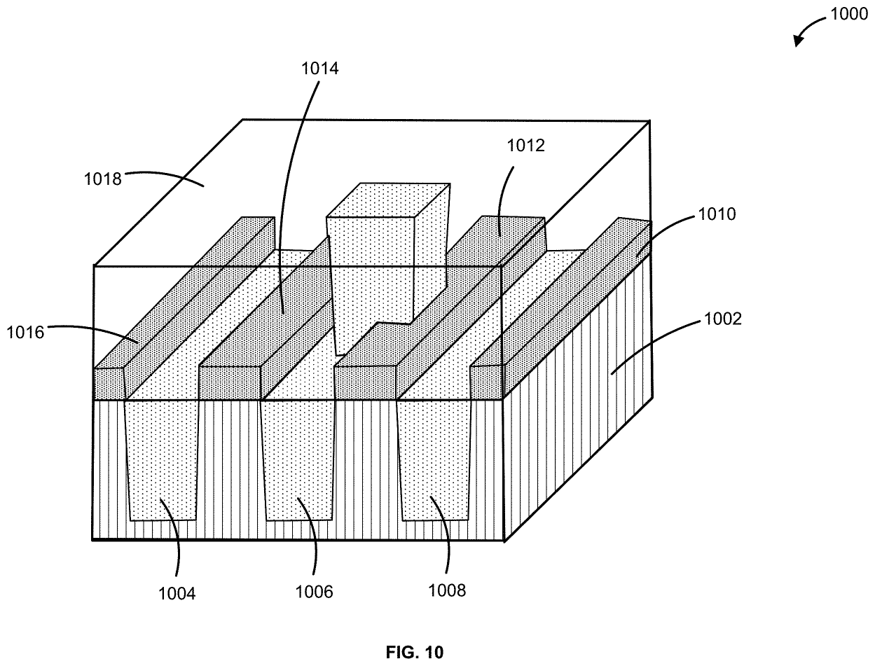

FIG. 10 illustrates a device structure 1000 in accordance with yet additional exemplary embodiments of the disclosure. Device structure 1000 include conductive features 1004-1008 formed within insulating material 1002, insulating structures 1010-1016, and a dielectric material layer 1018 overlying conductive lines 1004-1008 and insulating structures 1010-1016. Dielectric material layer 1018 can include a dielectric material layer formed using a method described herein. FIG. 10 illustrates use of dielectric material layer 1018 in back end of line (BEOL) fully aligned via (FAV) structures.

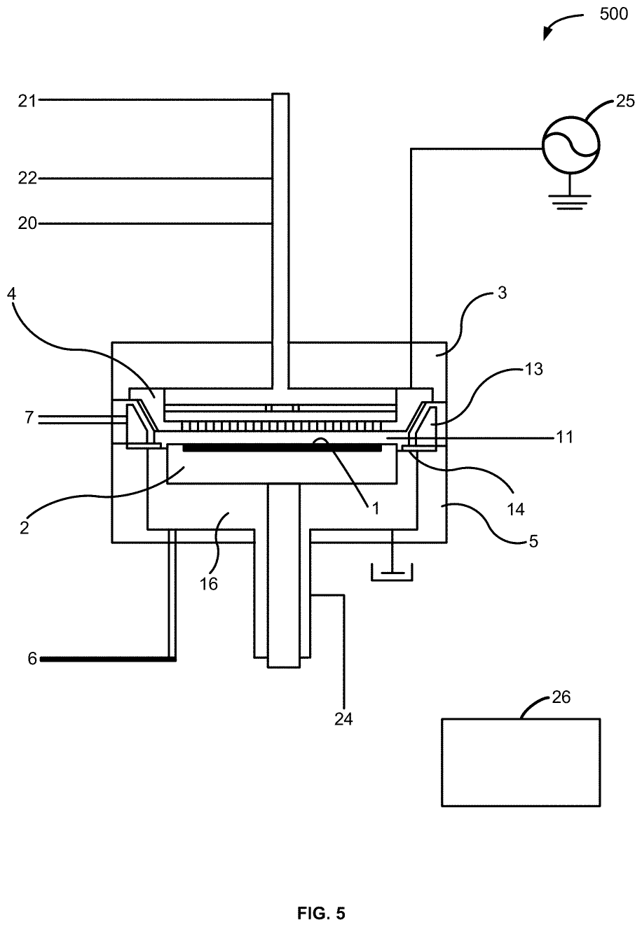

Turning now to FIG. 5, a reactor system 500 in accordance with exemplary embodiments of the disclosure is illustrated. Reactor system 500 can be used to perform one or more steps or sub steps as described herein and/or to form one or more structures or portions thereof as described herein.

Reactor system 500 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) and/or low frequency power from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 500 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition and treatment steps are performed in the same reaction space, so that two or more (e.g., all) of the steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming dielectric material on a surface of a substrate, the method comprising the steps of:
providing a substrate within a reaction chamber of a reactor system;
providing one or more precursors to the reaction chamber; and
providing pulsed plasma power to polymerize the one or more precursors within the reaction chamber.

2. The method of claim 1, further comprising a step of providing a reactant to the reaction chamber.

3. The method of claim 2, wherein the reactant comprises one or more of nitrogen and hydrogen.

4. The method of claim 3, wherein the reactant comprises one or more of NH₃, nitrogen, hydrogen, and amino family reactants, such as hydrazine, monomethylamine, dimethylamine, trimethylamine, monoethylamine, and diethylamine, in any combination.

5. The method of claim 3, wherein a volumetric ratio of the nitrogen and hydrogen reactant to the one or more precursors is less than 10 or about 3 to about 5.

6. The method of claim 2, wherein the reactant comprises an oxidant.

7. The method of claim 6, wherein a volumetric ratio of the oxidant to the one or more precursors is less than 10 or about 7 to about 10.

8. The method of claim 6, wherein the oxidant is selected from the group consisting of one or more of O₂, O₃, N₂O, N₂O₄, NₓO_{y}, CO, CO₂, H₂O, and H₂O₂, and an oxygen-containing (e.g., liquid) compound represented by the chemical formula: CₓH_{y}O_{z}, where x is between 1 and 5, y is between 4 and 16, and Z is between 1 and 4, such as methanol, ethanol, and isopropyl alcohol, in any combination.

9. The method of claim 1, wherein the method comprises a PECVD method.

10. The method of claim 1, wherein the process temperature is less than 450° C.

11. The method of claim 1, wherein a power to produce the pulsed plasma power is less than 2000 W.

12. The method of claim 1, wherein a frequency of power for the step of providing pulsed plasma power is an RF frequency from 1 kHz to 200 MHz with single or dual RF power sources.

13. The method of claim 1, wherein a pulse off time is greater than 2 times the pulse on time, or the RF on duty cycle is less than 50%.

14. The method of claim 1, wherein a frequency of power for the step of providing pulsed plasma power comprises a high RF frequency over 1 MHz and a low RF frequency below 500 kHz.

15. The method of claim 1, wherein the one or more precursors comprise a compound comprising silicon.

16. The method of claim 1, wherein the one or more precursors comprise a compound comprising carbon.

17. The method of claim 1, wherein the one or more precursors comprise a compound comprising a cyclic structure.

18. The method of claim 17, wherein the cyclic structure comprises silicon.

19. The method of claim 17, wherein the cyclic structure comprises silicon and oxygen.

20. The method of claim 1, wherein the one or more precursors comprise a compound comprising Si—O bonds.

21. The method of claim 1, wherein the one or more precursors comprise a compound comprising an organosilicon compound.

22. The method of claim 1, wherein the one or more precursors comprise one or more of octamethylcyclotetrasiloxane (OMCTS), tetramethylcyclotetrasiloxane (TMCTS), octamethoxydodecasiloxane (OMODDS), octamethoxycyclioiloxane, dimethyldimethoxysilane (DM-DMOS), diethoxymethlsilane (DEMS), dimethoxymethylsilane (DMOMS), phenoxydimethylsilane (PODMS), dimethyldioxosilylcyclohexane (DMDOSH), 1,3-dimethoxytetramethyldisiloxane (DMOTMDS), dimethoxydiphenylsilane (DMDPS), and dicyclopentyldimethoxysilane (DcPDMS).

23. The method of claim 1, wherein the one or more precursors comprise an amino-alkyl siloxane precursor.

24. The method of claim 23, wherein the amino-alkyl siloxane precursor comprises 1,3-bis(3aminopropyl)tetramethyldisiloxane.

25. The method of claim 1, wherein at least one of the one or more precursors comprises a ring structure comprising a chemical formula represented by —(Si(R₁,R₂)—O)ₙ—, where n ranges from about 3 to about 10.

26. The method of claim 25, wherein n=4 and R₁═R₂═CH₃.

27. The method of claim 25, wherein n=4, R₁═H, R₂═CH₃.

28. The method of claim 1, wherein at least one of the one or more precursors comprises a linear structure comprising a chemical formula represented by R₃—(Si(R₁,R₂)ₘ—O₍ₘ₋₁₎)—R₄, where m can range from about 1 to about 7.

29. The method of claim 28, wherein m=1, R₁═R₂═CH₃, and R₃═R₄═OCH₃.

30. The method of claim 28, wherein m=2, R₁═R₂═CH₃, and R₃═R₄═OCH₃.

31. The method of claim 28, wherein m=2, R₁═C₃H₆—NH₂, R₂═CH₃, and R₃═R₄═CH₃.

32. The method of claim 1, further comprising performing a post-deposition treatment comprising use of one or more of capacitively coupled plasma (CCP), microwave excitation, very high frequency (VHF) excitation, and ultraviolet (UV) excitation of/with an inert gas.

33. The method of claim 32, wherein a temperature of the substrate during the step of performing the post-deposition treatment is less than 500° C.

34. The method of claim 1, further comprising a thermal curing step.

35. The method of claim 34, wherein the step of thermal curing comprises providing one or more of COₓ, O₂, O₃, isopropyl alcohol, H₂O and inert gas to cure polymerized material.

36. The method of claim 34, wherein a temperature of the substrate during the step of the thermal curing is less than 500° C.

37. A structure comprising the dielectric material layer formed according to a method of claim 1.

38. The structure of claim 37, wherein a dielectric constant of the materials is between about 2.2 and about 4.2 or less than 10.

39. The structure of claim 37, wherein the structure comprises intermetallic features comprising one or more of Ru, Co, Cu, Ta, TaN, Ti, TiN, W, and wherein the dielectric material layer forms an intermetallic gap-fill layer between two or more of the features.

40. A FinFET device comprising a shallow trench isolation layer comprising the dielectric material layer formed according a method of claim 1.

41. A gate all around nanowire FET device comprising the dielectric material layer formed according a method of claim 1.

42. A cross-point device comprising the dielectric material layer formed according a method of claim 1.

43. A memory or logic device comprising a dielectric layer on BEOL IMD gapfill including dielectric (DOD) structure comprising the dielectric material layer formed according a method of claim 1.

44. A system for performing the steps of the method of claim 1.
